(19) United States
(12) Patent Application Publication
(10) Pub. No.: US 2013/0277573 A1
(43) Pub. Date: Oct. 24, 2013

(54) FUNCTIONALIZED CARBON MEMBRANES

(71) Applicants: John M. Miller, Eugene, OR (US); Janet Teshima, Rockaway Beach, OR (US); James E. Hutchison, Eugene, OR (US)

(72) Inventors: John M. Miller, Eugene, OR (US); Janet Teshima, Rockaway Beach, OR (US); James E. Hutchison, Eugene, OR (US)

(73) Assignee: Dune Sciences, Inc., Eugene, OR (US)

(21) Appl. No.: 13/978,177

(22) PCT Filed: Jan. 6, 2012
(86) PCT No.: PCT/US12/20545

§ 371 Date: Jul. 3, 2013

Related U.S. Application Data
(60) Provisional application No. 61/430,862, filed on Jan. 7, 2011.

(51) Int. Cl. H01J 37/20

(52) U.S. Cl. CPC H01J 37/20
USPC 250/440.11; 427/113; 427/595; 427/569

(57) ABSTRACT

Embodiments provide electron-conducting, electron-transparent substrates that are chemically derivatized (e.g., functionalized) to enhance and facilitate the deposition of nanoscale materials thereupon, including both hard and soft nanoscale materials. In various embodiments, the substrates may include an electron-conducting mesh support, for example, a carbon, copper, nickel, molybdenum, beryllium, gold, silicon, GaAs, or oxide (e.g., SiO₂, TiO₂, ITO, or Al₂O₃) support, or a combination thereof, having one or more apertures. In various embodiments, the mesh support may be coated with an electron conducting, electron transparent carbon film membrane that has been chemically derivatized to promote adhesion and/or affinity for various materials, including hard inorganic materials and soft materials, such as polymers and biological molecules.

### CROSS REFERENCE TO RELATED APPLICATIONS

The present application claims priority to U.S. Provisional Patent Application No. 61/430,862, filed Jan. 7, 2011, entitled “FUNCTIONALIZED CARBON MEMBRANES,” the disclosure of which is hereby incorporated by reference in its entirety.

### TECHNICAL FIELD

Embodiments herein relate to the field of substrates, and, more specifically, to functionalized substrates for transmission electron microscopy.

### BACKGROUND

Sample preparation in electron microscopy remains largely an art, and significant experience is needed in order to prepare artifact-free, reproducible, high-quality samples. This is true both for direct deposition methods, in which a material/species of interest is deposited from solution by one of several methods, including aerosol deposition, drop-casting, and, in some cases, freezing in a thin layer of solution, as well as for thin-section methods using embedded samples or focused ion beam specimens.

Carbon membranes are one of the primary types of substrates used in electron microscopy today, as they have a low background contribution for imaging, excellent flexibility and durability for extremely thin layers, good electronic conductivity to minimize charging, and relatively low cost. These carbon membranes can be either continuous, such as in graphene layers or amorphous carbon films, or perforated in patterned or random geometries to leave open spaces in the membrane. The membranes, ranging in thickness from a single atomic layer (graphene) up to 250 nm or more, are typically supported on a grid-form made from Cu or Ni with apertures. However, carbon is a relatively inert substrate, so sample preparation often involves glow-discharge cleaning to improve wettability. Carbon membranes also have no active surface to create an affinity for a particular material.

### BRIEF DESCRIPTION OF THE DRAWINGS

Embodiments will be readily understood by the following detailed description in conjunction with the accompanying drawings. Embodiments are illustrated by way of example and not by way of limitation in the figures of the accompanying drawings.

FIG. 1A illustrates a cross section of an unsupported, non-perforated carbon film; FIG. 1B illustrates a cross section of a perforated, unsupported film; FIG. 1C illustrates a cross section of a film supported by a non-perforated support; FIG. 1D illustrates a cross section of a film supported by a perforated support; and FIG. 1E illustrates a top view of the film illustrated in FIG. 1D, all in accordance with various embodiments;

FIG. 2A illustrates a functionalized carbon film; FIG. 2B illustrates a hydrophobic carbon film; FIG. 2C illustrates an amine-functionalized carbon film; FIG. 2D illustrates a hydrophilic, positively charged carbon film; FIG. 2E illustrates a negatively charged carbon film; and FIG. 2F illustrates a sulfhydryl(thiol)-functionalized carbon film, all in accordance with various embodiments;

FIGS. 3A and 3B illustrate a comparison of the features of non-functionalized carbon film substrates (FIG. 3A) versus functionalized carbon film substrates (FIG. 3B), in accordance with various embodiments;

FIG. 4 illustrates the processing steps involved in forming one example of a functionalized carbon film, in accordance with various embodiments;

FIGS. 5A and 5B illustrate some examples and applications of functionalized carbon films, where FIG. 5A illustrates the coupling of a functionalized carbon film with secondary molecules, and FIG. 5B illustrates the use of a functionalized carbon film for the immunocapture of target molecules, in accordance with various embodiments;

FIGS. 6A and 6B illustrate some examples and applications of functionalized carbon films, where FIG. 6A illustrates the use of heterobifunctional linkers to modify the functionalized substrates for selective capture of target species, and FIG. 6B illustrates a sandwich assay using functionalized carbon films, in accordance with various embodiments;

FIGS. 7A, 7B, 7C, and 7D are digital images illustrating the coverage of citrate-stabilized gold nanoparticles deposited on an amine-functionalized carbon substrate at three levels of magnification (FIGS. 7A, 7B, and 7C) versus a non-functionalized carbon substrate (FIG. 7D), in accordance with various embodiments;

FIGS. 8A and 8B are digital images comparing a non-functionalized grid (FIG. 8A) with an amine-functionalized carbon substrate (FIG. 8B) for 10 nm citrate-stabilized Au nanoparticles (NIST SRM 8011) showing the dramatically improved coverage of nanoparticles, in accordance with various embodiments;

FIG. 9 is a digital image illustrating the coverage of 2-3 nm propionate-functionalized Au NPs deposited on amine-functionalized carbon membrane, in accordance with various embodiments;

FIG. 10 is a digital image illustrating the coverage and contrast for a liposome sample deposited on an amine-functionalized grid using cryogenic EM, in accordance with various embodiments;

FIGS. 11A and 11B illustrate a comparison of a non-functionalized grid (FIG. 11A) with an amine-functionalized carbon substrate (FIG. 11B) for 30 nm citrate-stabilized Au nanoparticles (NIST SRM 8012), in accordance with various embodiments;

FIG. 12 is a digital image showing the coverage of 1.5 nm gold-trimethylammoniumethanethiol (TMAT)-functionalized particles deposited on a 3 nm thick supported carbon membrane; in accordance with various embodiments;

FIG. 13 illustrates a micrograph of T3 phage captured on an epoxy-functionalized carbon TEM grid, in accordance with various embodiments; and

FIG. 14 illustrates the use of Protein A modified carbon film for the immunocapture and imaging of the Complex I enzyme from a mixed solution of bovine heart mitochondria (BHM), in accordance with various embodiments.

### DETAILED DESCRIPTION OF DISCLOSED EMBODIMENTS

In the following detailed description, reference is made to the accompanying drawings which form a part hereof, and in which are shown by way of illustration embodiments that may be practiced. It is to be understood that other embodiments may be utilized and structural or logical changes may be made without departing from the scope. Therefore, the following detailed description is not to be taken in a limiting sense, and the scope of embodiments is defined by the appended claims and their equivalents.

Various operations may be described as multiple discrete operations in turn, in a manner that may be helpful in understanding embodiments; however, the order of description should not be construed to imply that these operations are order dependent.

The description may use perspective-based descriptions such as up/down, back/front, and top/bottom. Such descriptions are merely used to facilitate the discussion and are not intended to restrict the application of disclosed embodiments.

The terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

For the purposes of the description, a phrase in the form “A/B” or in the form “A and/or B” means (A), (B), or (A and B). For the purposes of the description, a phrase in the form “at least one of A, B, and C” means (A), (B), (C), (A and B), (A and C), (B and C), or (A, B and C). For the purposes of the description, a phrase in the form “(A)B” means (B) or (AB) that is, A is an optional element.

The description may use the terms “embodiment” or “embodiments,” which may each refer to one or more of the same or different embodiments. Furthermore, the terms “comprising,” “including,” “having,” and the like, as used with respect to embodiments, are synonymous.

As used herein, the terms “substrate,” “membrane,” “film”, and their derivatives, are used herein to refer to a thin layer, for instance of carbon, that may be used to support a specimen during TEM. In some embodiments, the surface of such a substrate, membrane, or film may be functionalized in accordance with various methods described herein. As used herein, the terms substrate, membrane, and film refer only to the membrane itself, exclusive of any additional supporting structures.

As used herein, the term “aryl” refers to any functional group or substituent derived from an aromatic ring, such as phenyl, naphthyl, thienyl, indolyl, etc.

As used herein, the term “alkyl” refers to a cyclic, branched, or straight chain alkyl group containing only carbon and hydrogen, and unless otherwise mentioned contains one to twelve carbon atoms. This term may be further exemplified by groups such as methyl, ethyl, n-propyl, isopropyl, isobutyl, t-butyl, pentyl, hexyl, heptyl, adamantyl, and cyclopentyl. Alkyl groups may either be unsubstituted or substituted with one or more substituents, for instance, halogen, het, alkyl, cycloalkyl, cycloalkenyl, alkoxy, alkylthio, trifluoromethyl, acyloxy, hydroxy, mercapto, carboxy, aryloxy, aryl, arylalkyl, heteroaryl, amino, alkylamino, dialkylamino, cyano, nitro, morpholino, piperidino, pyrrolidin-1-yl, piperazin-1-yl, or other functionality.

As used herein, the term “alkenyl” refers to a hydrocarbon group formed when a hydrogen atom is removed from an alkene group.

As used herein, the term “amine” refers to NH₂, NHR, or NR₂. Unless otherwise stated, R can be alkyl, alkenyl, alkynyl, cycloalkyl, cycloalkenyl, het or aryl.

As used herein, the term “carboxyl” refers to a functional group that includes a carbonyl (RR′C═O) and a hydroxyl (R—O—H). A carboxyl has the formula —C(═O)OH, usually written as —COOH or —CO₂H.

As used herein, the term “carbonyl” refers to a functional group composed of a carbon atom double-bonded to an oxygen atom: C═O. Carbonyls are common to several classes of organic compounds as part of many larger functional groups.

As used herein, the term “sulfhydryl” refers to an organosulfur compound that contains a carbon-bonded sulfhydryl (—C—SH or R—SH) group (where R represents an alkane, alkene, or other carbon-containing group of atoms).

As used herein, the term “phosphonate” refers to an organic compound containing one or more C—PO(OH)₂ or C—PO(OR)₂ groups (where R═alkyl, aryl).

As used herein, the term “sulfonate” refers to a salt or ester of a sulfonic acid. It contains the functional group R—SO₂O—.

As used herein, the term “epoxy” refers to a compound in which an oxygen atom is directly attached to two adjacent or non-adjacent carbon atoms of a carbon chain or ring system, thus epoxies are cyclic ethers. The term epoxide represents a subclass of epoxy compounds containing a saturated three-membered cyclic ether, and are thus called oxirane derivatives.

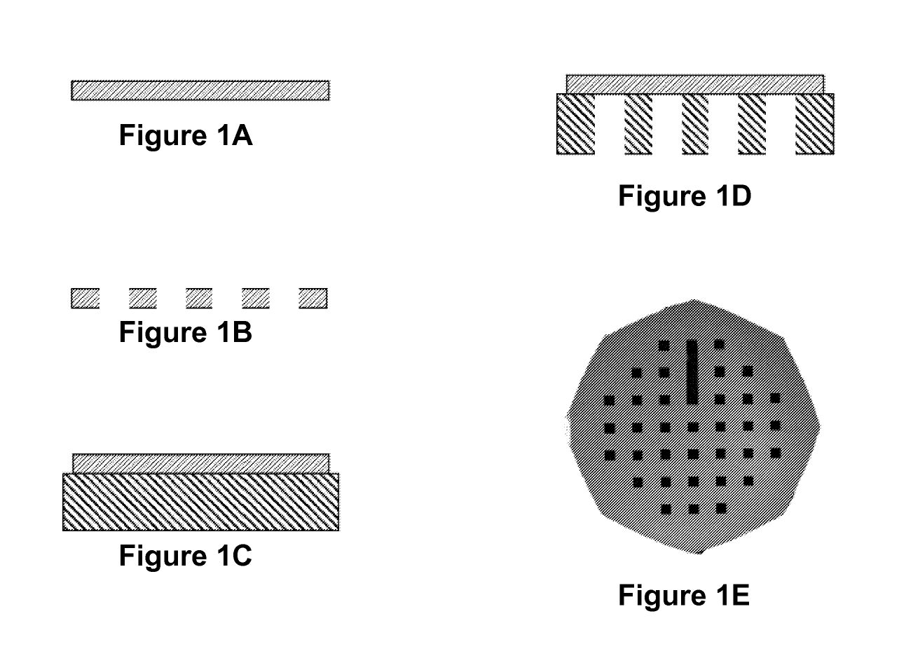

Disclosed in various embodiments are electron-conducting, electron-transparent substrates that are chemically derivatized (e.g., functionalized) to enhance and facilitate the deposition of nanoscale materials thereupon, including both hard and soft nanoscale materials. In various embodiments, the substrates may include an electron-conducting mesh support, for example, a carbon, copper, nickel, molybdenum, beryllium, gold, silicon, GaAs, or oxide (e.g., SiO₂, TiO₂, ITO, or Al₂O₃) support, or a combination thereof, having one or more apertures. In various embodiments, the mesh support may be coated with an electron conducting, electron transparent carbon film membrane that has been chemically derivatized to promote adhesion and/or affinity for various materials, including hard inorganic materials and soft materials, such as polymers and biological molecules. FIGS. 1A-1E illustrate several examples of functionalized carbon films: FIG. 1A illustrates a cross section of an unsupported, non-perforated carbon film, FIG. 1B illustrates a cross section of a perforated, unsupported film, FIG. 1C illustrates a cross section of a film supported by a non-perforated support, FIG. 1D illustrates a cross section of a film supported by a perforated support, and FIG. 1E illustrates a top view of the film illustrated in FIG. 1D, in accordance with various embodiments.

Existing substrates for electron microscopy applications generally use electron transparent substrates that are not chemically functionalized to promote interactions with the target material to be characterized. For example, in a typical application using existing technologies, carbon-membrane grids (perforated or continuous) are glow-discharged in order to improve the hydrophilic character of the surface, and the sample is either drop-cast, immersed, or otherwise deposited on the grid surface. There is no affinity between the substrate (e.g., grid) and the material of interest, and thus a combination of experience, skill, and luck is required in order to avoid sample preparation artifacts, such as drying, agglomeration, and/or poor sample coverage.

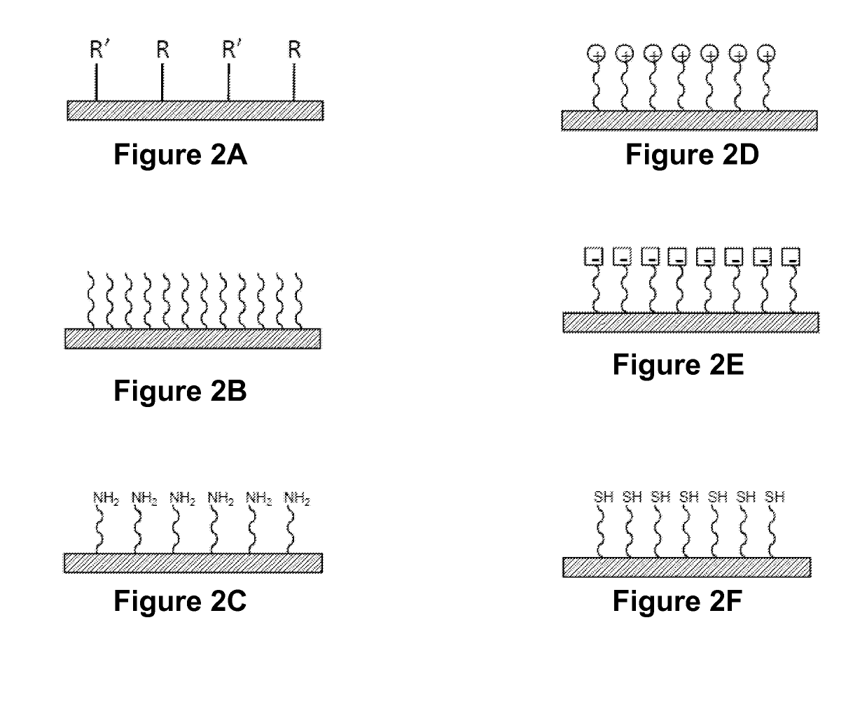

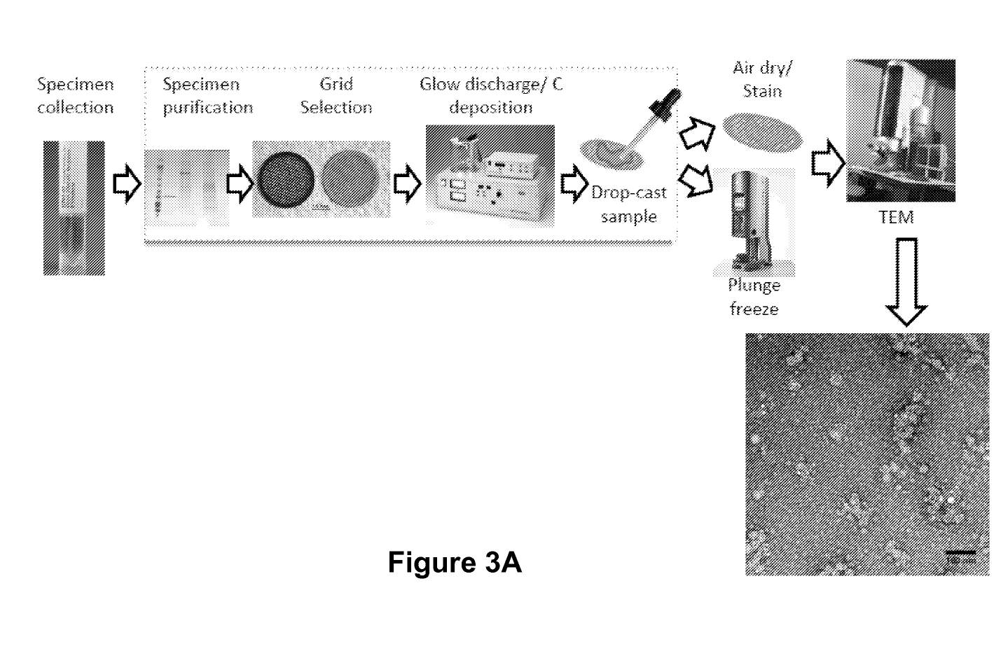

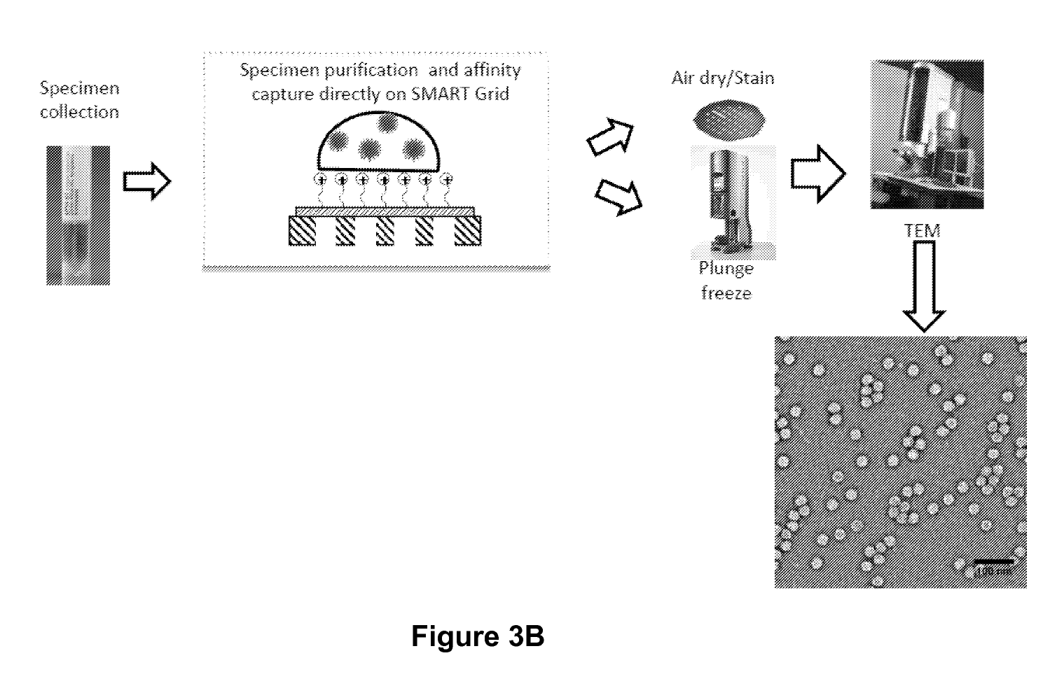

By contrast, the chemically derivatized carbon substrates disclosed in various embodiments herein may enhance the deposition of nanoscale materials on their surfaces, such as both hard and soft sample materials. For example, in various embodiments, the disclosed derivatized substrates may eliminate artifacts created by drying effects. In addition, in various embodiments, the disclosed substrates may improve sample dispersion and provide uniform and controlled coverage of materials deposited on their surface. Thus, in various embodiments, the disclosed functionalized carbon substrates may dramatically improve specimen preparation for various technologies, such as those related to the characterization of structural and/or functional properties of the specimen, for instance electron microscopy (EM), or, more specifically, transmission electron microscopy (TEM). Thus, in various embodiments, the disclosed substrates may be used for a variety of purposes, such as biological EM, immunoEM, cryoEM, structural biology, virus detection, and nanomaterial imaging. In various embodiments, the disclosed substrates also may be used to enhance other nanoscale measurement tools, including surface analytical methods, scanning electron microscopy, and optical microscopy. In addition, in various embodiments, the electron transmissive functionalized carbon membranes disclosed herein may be used in a variety of other applications, including sensors/biosensors, in photovoltaics as a transparent conductive bonding layer, and as substrates for catalyst deposition and nanowire growth, for example. FIG. 2 illustrates several types of functionalized electron transmissive carbon films; FIG. 2A illustrates a functionalized carbon film; FIG. 2B illustrates a hydrophobic carbon film; FIG. 2C illustrates an amine-functionalized carbon film; FIG. 2D illustrates a hydrophilic, positively charged carbon film; FIG. 2E illustrates a negatively charged carbon film; and FIG. 2F illustrates a sulfhydryl (thiol)-functionalized carbon film, all in accordance with various embodiments. FIGS. 3A and 3B illustrate a comparison of the features of non-functionalized carbon film substrates versus functionalized carbon film substrates, in accordance with various embodiments.

Additionally, in various embodiments, the disclosed derivatized substrates may permit new opportunities for sample preparation for transmission electron microscopy (TEM) and other analytical characterization methods that cannot be achieved with existing carbon based films. For example, in some embodiments, the affinity of the disclosed substrates may be tuned to match one or more desired properties of the target materials, for example, through charge interactions, chemical bonding, or hydrogen bonding. In other embodiments, the disclosed substrates may allow for on-grid affinity-based purification of target analytes from complex solutions, including biomolecules, pharmaceuticals, nanoparticles, and the like. In various embodiments, the disclosed functionalized carbon substrates may allow for on-grid immunoassays to isolate biomolecular interactions, or may be used to concentrate dilute solutions of analytes (e.g., virus solutions). In some embodiments, the substrates may reduce handling/processing requirements, and/or may allow for the rinsing of grids (e.g., substrates) to remove unwanted material that is not tethered, bonded, or otherwise affixed to the substrate surface. In other embodiments, the disclosed substrates may enable environmental monitoring of the fate of nanomaterials, and/or may allow for improved sample dispersion for cryoEM whereby samples with target molecules attached can be plunge-frozen.

Furthermore, in nanomaterials sample preparation, the functionalized carbon substrates described herein may provide a simple approach to the capture and/or deposition of materials from solution. In various embodiments, functionalized carbon substrate surfaces with affinity for nanoparticles may be used to prepare a wide range of samples for characterization including metals, polymers, semiconductors, oxides, and chalcogenides, and may also be used to deposit materials for devices such as quantum dots for solar cells, catalysts and/or electrocatalysts, metal nanoparticles for sensing applications, and the like.

Thus, disclosed in various embodiments are electron transmissive substrates that may include a carbon or carbon-containing film, and the film may include at least one functionalized surface. Functionalized silicon grids are disclosed in U.S. patent application Ser. No. 11/921,056, entitled SILICON SUBSTRATES WITH THERMAL OXIDE WINDOWS FOR TRANSMISSION ELECTRON MICROSCOPY, and Ser. No. 12/600,764, entitled TEM GRIDS FOR DETERMINATION OF STRUCTURE-PROPERTY RELATIONSHIPS IN NANOTECHNOLOGY, both of which are incorporated by reference herein in their entirety. However, while the functionalized surfaces disclosed in these applications create a strong affinity for a variety of materials, they have some fundamental limitations that have prevented their widespread adoption. These include intermittent membrane vibration due to charging, background contribution for low contrast materials under normal and low dose conditions, and limited compatibility for cryoEM. By contrast, the disclosed functionalized carbon substrates avoid charging and the resulting intermittent vibration, they do not contribute to background, and they are compatible with cryoEM.

Prior to the present disclosure, methods of functionalizing carbon membranes were not known, and the chemistry involved with functionalizing SiO₂ grids is inapplicable to carbon membranes. The surface chemistry of carbon materials (e.g., carbon black or carbon nanotubes) typically is manipulated by refluxing the material in concentrated acids or anodic oxidation to improve reactivity, solubility, sorption capacity etc. However, this approach is inappropriate for the thin (in many cases only a few atoms-thick), functionalized carbon membranes disclosed herein, which may not be able to withstand these traditional processing conditions. In addition, in various embodiments, chemical compatibility issues may further complicate the functionalization of supported carbon films. For example, metal supports such as Cu may be easily oxidized (and may readily dissolve in acids), and thus may force delamination of the carbon membrane. Thus, existing methods for introducing chemical function to other carbon materials may not be used for functionalizing carbon films.

Other forms of carbon also generally may not be electron transmissive. In general, electron microscopy requires the use of clean background films with minimal variations in the electron density across the surface of the membrane. Thus, the membranes disclosed herein generally have a highly uniform thickness not required of other forms of carbon. Thus, existing methods for introducing chemical function to other carbon materials may not be used for functionalizing carbon films, as the chemical steps involved may be incompatible with the degree of uniformity displayed by the functionalized membranes disclosed herein.

Furthermore, the covalent bonding of molecules to carbon can be challenging due to the requirement for the correct surface reactive species and the susceptibility for oxidation. Typically, carbon TEM grids may be glow-discharged prior to use in order to impart hydrophilicity to the carbon surface. However, this hydrophilicity is transient, and may last only a few minutes before the surface functionality is oxidized away, leaving the hydrophobic surface. By contrast, the covalent linkage of the functional chemistry disclosed herein may enable preservation of the functionality of the functionalized carbon substrates for weeks or months.

In various embodiments, the functionalized carbon film may be perforated, whereas in other embodiments, the film maybe continuous. In embodiments, wherein the film is perforated, the perforations may be random or they may be patterned, and the perforations may have a diameter of from about 50 nm to about 5 microns, for example, from about 100 nm to about 4 microns, or from about 250 nm to about 3 microns.

In various embodiments, the carbon film of the electron transmissive, functionalized carbon substrates may include, in specific, non-limiting examples, amorphous carbon, single or multi-layer graphene sheets, holey carbon films, reticulated carbon films, lacey carbon films, diamond carbon films, or carbon-filled polymer membranes (including carbon black, carbon fullerenes, among others). In various embodiments, the perforated films may include a patterned array of perforations, such as in holey carbon, or the perforations may be random, such as with lacey carbon. In various embodiments, the carbon films may be non-woven or woven, and may include substrates such as carbon nanotube mats.

In some embodiments, the carbon film may be freestanding, whereas in other embodiments, the substrate may include a support structure, such as a carbon, copper, nickel, molybdenum, beryllium, gold, silicon, GaAs, oxide (e.g., SiO₂, TiO₂, indium tin oxide, or Al₂O₃), nitride (e.g., Si3N4), or polymer support structure, or a combination thereof. In some embodiments, the carbon film may span one or more electron transmissive apertures in the support structure, and in particular embodiments, the carbon film may be optically transmissive. In various embodiments, the carbon film may have a thickness that may range from about 0.1 nm to about 250 nm, for example, about 0.5 nm to about 100 nm, or from about 1 nm to about 50 nm.

In various embodiments, the functionalized surface may comprise a compound having the formula C—R, wherein R may include a silane, an aryl, an alky, an alkenyl, an amine, a carboxyl, a carbonyl, a sulfhydryl, a phosphonate, a sulfonate, or an epoxy. In some embodiments, R may be a chemical linker to a biomolecule, such as a maleimide, an NHS-ester, or a carbodiimide. In other embodiments, R may be a biological molecule, such as a protein, an antibody, or a virus. In some embodiments, the functionalized surface may be either a monolayer or a multilayer, and in some embodiments, the functionalized surface may be hydrophilic.

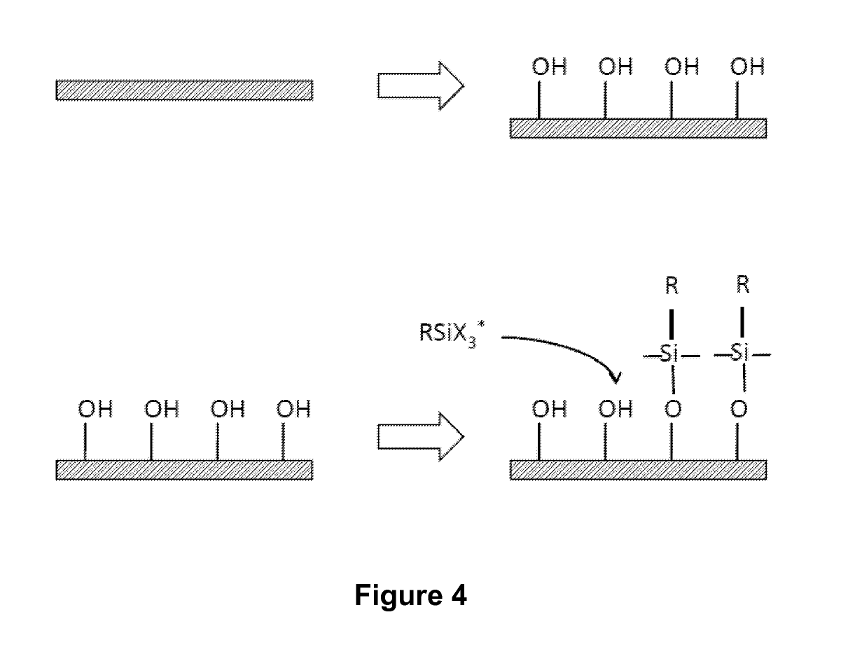

Also disclosed in various embodiments are methods of functionalizing an electron transmissive and electron conductive carbon or carbon-containing film. In some embodiments, the method may include surface-oxidizing at least one surface of the film and reacting the surface-oxidized film with one or more organosilane derivatives to form a siloxane bond with the film, thereby silanizing the surface of the film. In some embodiments, the silanized film surface may have the formula C—O—Si—R₃, wherein C describes the at least one surface of the film, —O—Si describes the siloxane bond, and R includes one or more functional groups. In various embodiments, oxidizing the surface of the film may include using a mild oxidant, and in particular embodiments, the mild oxidant may include dilute UV/ozone, ozone, H₂O₂, oxygen plasma, or an acid. In some embodiments, the carbon film may be surface-oxidized to a desired degree, such as from about 0.2 to about 1 —OH/nm². In various embodiments, this mild oxidation of the film may introduce hydroxyl functionality. In some examples, surface hydroxyls may interact with silane precursors in a condensation type reaction to form C—O—Si. FIG. 4 illustrates the processing steps involved in forming one example of a functionalized carbon film, in accordance with various embodiments;

In various embodiments, the organosilane derivative may have the formula: RSiX₃, R₂SiX₂, R₃SiX, or a combination thereof, or R-silatrane (R-2,8,9-trioxa-5-aza-1-silabicyclo(3.3.3)undecane), wherein X may include a chloride, a bromide, an alkoxy group that includes a straight-chain or branched C₁-C₃₀ radical, a phenoxy, a benzyloxy, or a naphthoxy; and R may include an aryl, an alkyl, an alkenyl, an amine, a carboxyl, a carbonyl, a sulfhydryl, a phosphonate, a sulfonate, or an epoxy. In other embodiments, R may be a chemical linker to a biomolecule, such as a maleimide, an NHS-ester, or a carbodiimide. In still other embodiments, R may be a biological molecule, such as a protein, an antibody, or a virus.

In various other embodiments, reacting the surface of the film with one or more organosilane derivatives may include exposing the surface of the film to a vapor phase of an organosilane derivative at a temperature of from about 25° C. to about 100° C. in an ambient or inert atmosphere, such as from about 35° C. to about 90° C., from about 45° C. to about 80° C., or from about 55° C. to about 70° C. In some embodiments, reacting the surface of the film with one or more organosilane derivatives may include reacting the at least one surface of the film in liquid phase with the organosilane derivative dissolved or dispersed in aqueous or nonaqueous solvent. In other embodiments, reacting the film surface with one or more organosilane derivatives may include contacting the at least one surface of the film with the liquid phase by immersion, floating, adding a droplet to the surface of the film, spray coating, spin-coating, or dip-coating.

In further embodiments, the method may also include a post-exposure process step such as heat treatment or rinsing. In some embodiments, an additional surface modification procedure may be applied after silanization to further modify the surface properties of the functionalized carbon substrate, for example to enhance affinity for target materials. In various embodiments, such modification may include reacting with bi-functional linkers such as EDC (1-Ethyl-3-[3-dimethylaminopropyl]carbodiimide Hydrochloride), SMCC (succinimidyl 4-[N-maleimidomethyl]cyclohexane-1-carboxylate) or sulfo-SMCC, BS³ (Bis[sulfosuccinimidyl]suberate), Sulfo-NHS, or other homobifunctional or heterobifunctional linker molecules. In addition, in some embodiments, this step may involve conjugating biomolecules directly to the functionalized carbon substrate surface, such as nucleic acids, antibodies, proteins, viruses, antigens, and oligopeptides.

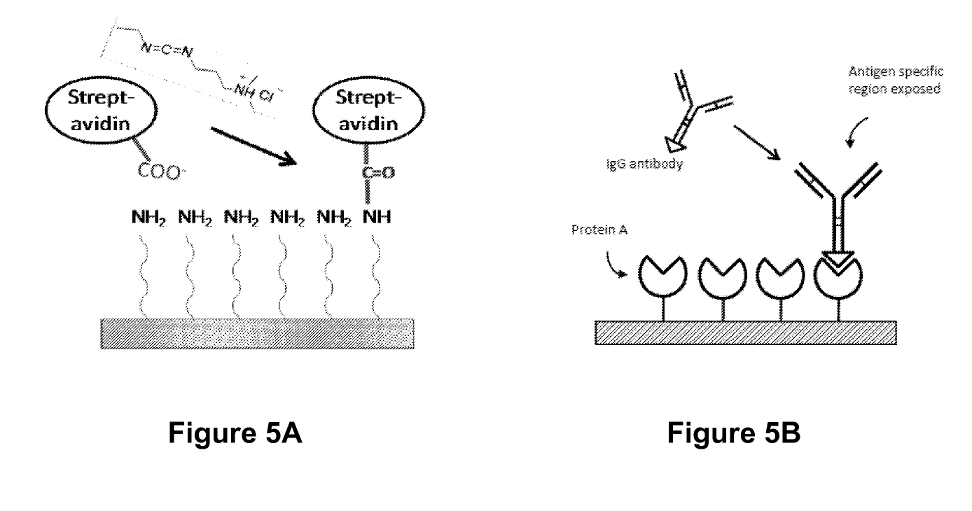

FIGS. 5A and 5B illustrate some examples and applications of functionalized carbon films, in accordance with various embodiments. FIG. 5A illustrates the coupling of a functionalized carbon film with secondary molecules. In this case, streptavidin is coupled to an amine-functionalized carbon film using a bifunctional linker molecule (e.g., EDC). The streptavidin-functionalized grid may then capture biotin-labeled molecules. FIG. 5B illustrates the use of a functionalized carbon film for the immunocapture of target molecules. In this example, protein A is coupled with either an amine-functionalized carbon film or an epoxy-functionalized carbon film, either directly or via a linker. In this example, Protein A may then selectively capture IgG antibodies such as on virus particles or other biological molecules.

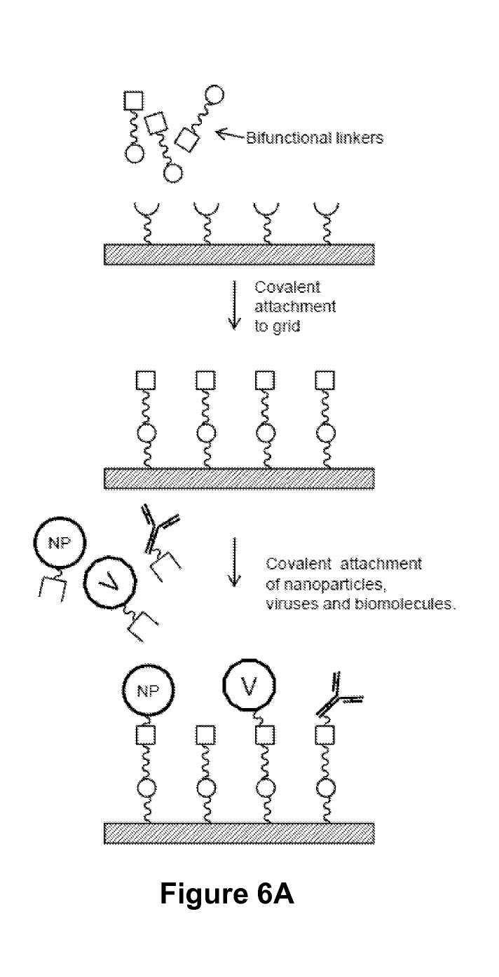

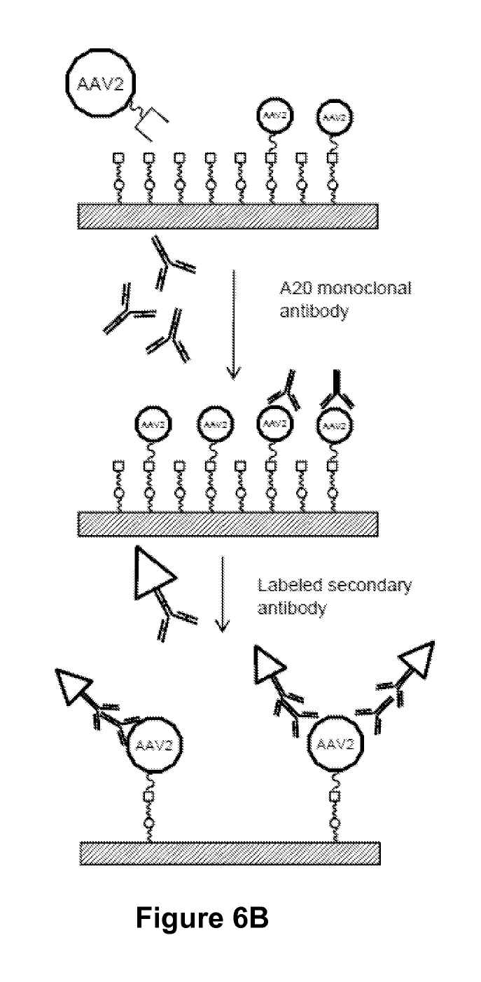

FIGS. 6A and 6B illustrate additional examples and applications of functionalized carbon films, in accordance with various embodiments. FIG. 6A illustrates a use of a functionalized carbon film for covalent binding to nanoparticles, biological molecules such as antibodies, viruses, proteins, nucleic acids, and the like. In the illustrated example, heterobifunctional linkers may be used to modify the functionalized substrates for selective capture of target species. Specific examples of suitable reactive groups include sulfhydryl, NHS, esters, and the like. FIG. 6B illustrates a sandwich assay using functionalized carbon films. In this example, a bifunctional linker is bound to an amine-functionalized carbon film, and the linker may specifically covalently bind to the primary amine groups on the adeno-associated virus (AAV2) from purified solutions. After blocking the surface with an appropriate blocker, such as bovine serum albumin or powdered milk, the primary antibody (in this case, A20) binds to the AAV2 and a secondary antibody that is labeled with a gold nanoparticle or fluorescent tag is attached.

In various embodiments, the surface of the film may be silanized in a pattern to provide at least two regions of the at least one surface of the film with different surface chemistries, and in particular embodiments, the pattern may be a regular pattern, such as an array of functionalized regions, or it may be an irregular pattern. In some embodiments, the pattern may include one or more areas that are not functionalized, and in particular embodiments, the pattern may be a microarray.

The functionalized carbon substrates disclosed herein have a broad range of potential applications beginning with the basic characterization and imaging of materials (inorganic or organic/biological) on the nanoscale using electron microscopy. In various embodiments, the ability to tether materials to the surface may allow for multi-step processing and correlative analysis of these materials, including electron microscopy and assortment of embedded analytical tools (e.g., eels, EDAX, electron diffraction). In addition, in various embodiments, a wide assortment of other analytical methods including XPS, UPS, AES, TOF-SIMS, EPMA, etc. may be used to characterize the surface properties of deposited materials. Additionally, in various embodiments, these substrates may be used for optical interrogation including fluorescence microscopy. In one specific, non-limiting example, fluorescence microscopy may be used to isolate an area of interest in a sample, and then to zoom-in to much higher magnification. In various embodiments, the disclosed substrates may be used for both basic and applied research, as well as for commercial applications such as for quality control of nanomaterials or pharmaceuticals.

In one specific, non-limiting example, the disclosed functionalized carbon substrates may be used for cryoEM. In this example, the substrate may be functionalized with an appropriate chemistry to promote capture and/or binding of biomolecules, cells, or compounds such as pharmaceuticals (for example, suitable surfaces may include epoxy, amine, antibody modified, and linker-mediated surfaces). In this example, the sample may be incubated with the functionalized carbon substrate to facilitate capture, and the solution would then be mostly wicked off the functionalized carbon substrate immediately prior to being plunged into liquid ethane to instantly freeze the sample (and create vitreous ice). Without being bound by theory, the non-crystalline ice may preserve the three-dimensional structure of the captured molecules for imaging in TEM. In various embodiments, the described functionalized carbon substrates may be well-suited to take advantage of better selectivity to isolate intermolecular and intramolecular interactions.

In another specific, non-limiting example, the disclosed functionalized substrate may be functionalized with the appropriate chemistry to create a hydrophilic surface. In various embodiments, a hydrophilic surface may improve wettability of the solution sample, for instance to improve the uniformity of the resulting sample for traditional EM and/or cryoEM.

In other embodiments, other specific EM applications may include virus identification and clinical diagnosis. For example, in some embodiments, the substrate may be modified for the capture of specific molecules of interest or specific classes of molecules of interest. In various embodiments, this may be achieved with immunocapture or through other affinity based capture techniques. In various embodiments, the functionalized carbon substrates may allow for the capture of specific molecules from a complex solution, such as blood or saliva. In some embodiments, the functionalized carbon substrates may serve as a diagnostic platform for the direct imaging of the target species (e.g., virus, bacteria, etc.) In some embodiments, in a clinical setting, the functionalized carbon substrates may be incubated with a patient's sample, and then the substrates may be immediately dried, stained, and imaged using a TEM. In various embodiments, this approach may be advantageous because of the selectivity for what is being imaged.

By contrast, in existing EM-based viral diagnostics, if samples are prepared from crude sample mixtures, everything is deposited on the grid, and the user is left to categorize viruses based solely on their geometry. In various embodiments described herein, with selectivity-enhanced functionalized carbon substrates, it may be possible to identify particular pathogens, such as particular viruses. In some embodiments, when different areas of the functionalized carbon substrate are patterned with different antibodies, for example, screening for a wide range of viruses may be enabled. In various embodiments, this type of testing may be carried out for a wide range of different molecules, including antibodies, proteins, enzymes, viruses, and bacteria.

In other embodiments, the functionalized carbon substrates described herein may be used for imaging of nucleic acids and specifically labeled nucleic acids for gene sequencing. In various embodiments, TEM may be used to sequence long strands of DNA. In some embodiments, the use of functionalized carbon substrates may be advantageous to minimize the background for single atom labels or nanoparticle labels.

Other embodiments of the functionalized carbon substrates may be used for the capture of airborne or liquid borne nanoparticulate materials for environmental monitoring of effluents, or even workplace exposure. In these examples, the functionalized carbon substrates may be functionalized to promote the capture of target nanomaterials from either liquid or air. In some examples, using an appropriate sampling cartridge, materials may be captured, such as carbon nanotubes, which cannot be monitored using existing methods unless the concentrations are extremely high. In various embodiments, this approach may minimize artifacts in sample preparation that can lead to misinterpretation. For example, many existing methods rely on the use of filters that are burned to leave behind the materials of interest. This burning process could fundamentally change some of the key parameters of interest including particle size and morphology, but it is unnecessary when the disclosed functionalized carbon substrates are used.

In addition to specific embodiments for using electron microscopy with the functionalized electron transmissive, electron conductive functionalized carbon substrates, in some embodiments, the functionalized carbon films may also be used as tunneling junctions to improve the tunneling efficiency for semiconductor devices. In some embodiments, the functionalized carbon films may be used in photovoltaics as conductive layers to capture, e.g., quantum dots, to improve their quantum yield. In additional embodiments, the functionalized carbon substrates may be used for biosensors when depositing metal nanoparticles.

### EXAMPLES

The following examples are provided to illustrate some of the foregoing embodiments, and are not intended to be limiting.

### Example 1

### Amine-Functionalized Amorphous Carbon Films

This example illustrates the efficacy of amine-functionalized amorphous carbon films. Amorphous carbon films having a thickness of 3 nm were deposited on lacey carbon and copper supports, and were oxidized using UV/ozone for five minutes at ambient temperature and atmosphere. These substrates were then exposed to vapors of aminopropyltrimethoxysilane for 18 hours in an enclosed desiccated chamber at room temperature. Subsequently, the samples were removed and equilibrated at room temperature for 24 hours, although in other examples, the samples could be rinsed in water to remove and/or react any unreacted silane precursor.

The aminopropyltrimethoxysilane-functionalized carbon substrates possessed a positive surface charge due to the primary amine and were able to attract negatively charged species. In addition, in other examples, molecular linkers such as BS3 could be used to capture biological molecules such as viruses or antibodies.

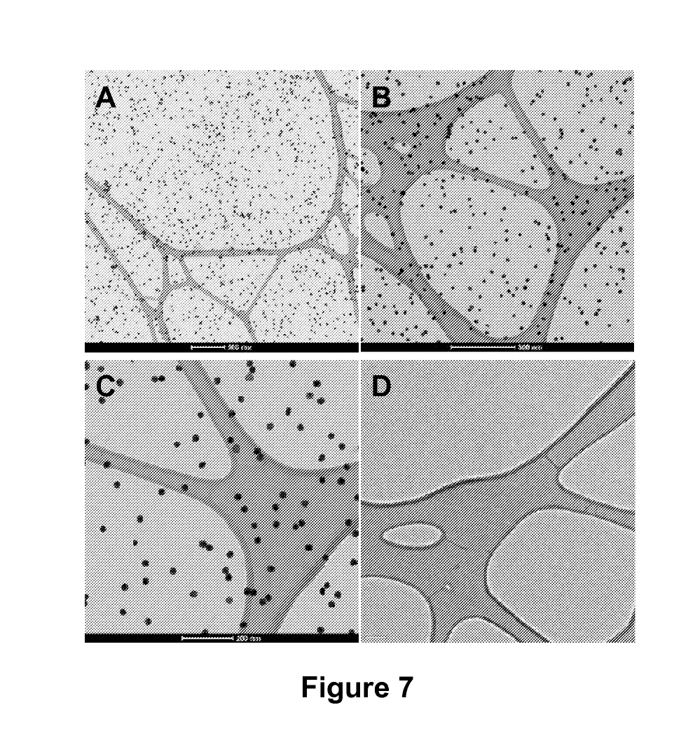

FIGS. 7A, 7B, 7C, and 7D illustrate the coverage of citrate-stabilized gold nanoparticles deposited on an amine-functionalized carbon substrate at three levels of magnification (FIGS. 7A, 7B, and 7C) versus a non-functionalized carbon substrate (FIG. 7D), in accordance with various embodiments. The samples were prepared by floating the functionalized carbon substrate on a droplet of Au citrate nanoparticles (NIST SRM8013) for 5 minutes followed by rinsing of the functionalized carbon substrate in deionized water and air drying. The image in the lower right (FIG. 7D) was not functionalized. In contrast with FIGS. 7A, 7B, and 7C, the non-functionalized carbon substrate did not capture any particles.

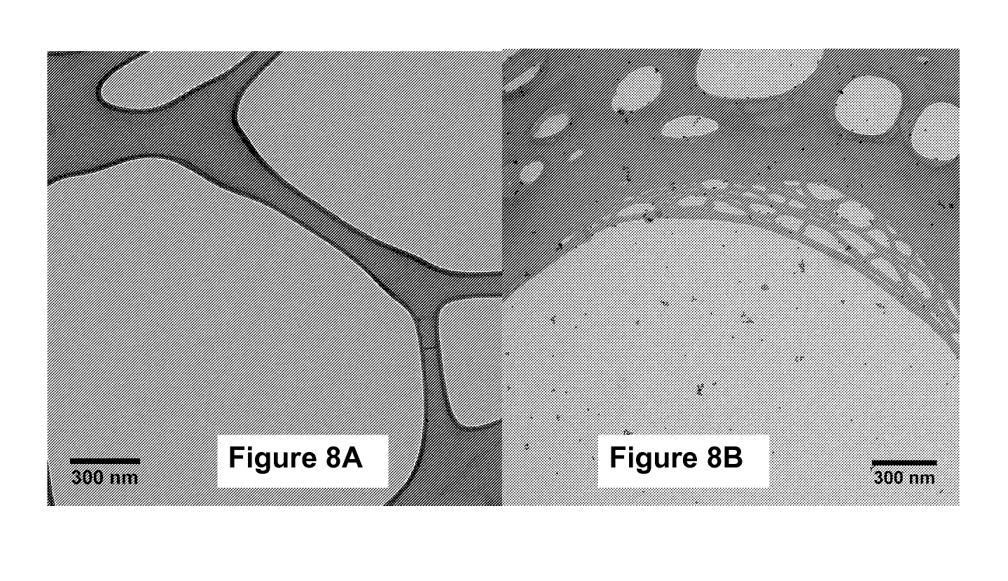

In another example of the efficacy of the amine-functionalized carbon substrates, FIGS. 8A and 8B illustrate a comparison of a non-functionalized grid (FIG. 8A) with an amine-functionalized carbon substrate (FIG. 8B) for 10 nm citrate-stabilized Au nanoparticles (NIST SRM 8011), showing the dramatically improved coverage of nanoparticles, in accordance with various embodiments. A few particles stuck to the fibrils of the non-functionalized grid, but virtually no other particles could be found.

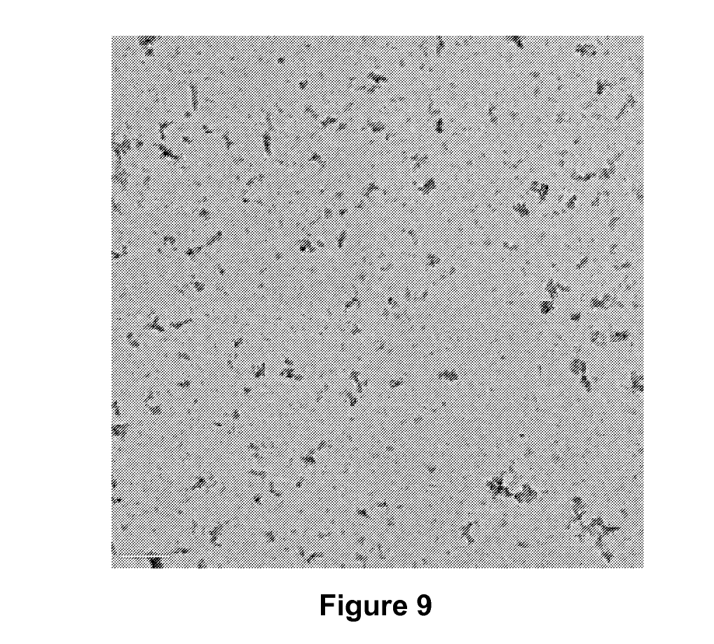

In yet another example, FIG. 9 is a digital image illustrating the coverage of 2-3 nm propionate-functionalized Au NPs deposited on an amine-functionalized carbon membrane, in accordance with various embodiments. In this embodiment, the membranes are 5-10 nm in thickness with no lacey carbon and from a different supplier (Pacific Grid Technology). The propionate is negatively charged and is electrostatically attracted to the amine-carbon surface. This amine-functionalized carbon substrate showed good coverage of the nanoparticles.

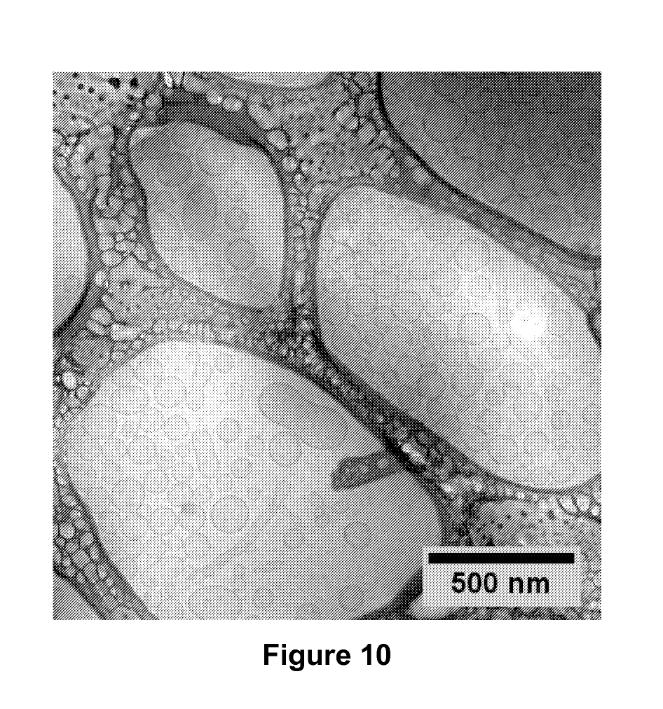

In still another example, FIG. 10 is a digital image illustrating the coverage and contrast for a liposome sample deposited on an amine-functionalized grid using cryogenic EM, in accordance with various embodiments. In this embodiment, the sample was prepared by depositing a 2 μl droplet of liposome solution on the amine-functionalized surface of the 3 nm carbon film on lacey carbon, followed by a 5 minute incubation. The grid was then blotted with filter paper for 2 seconds and then plunge-frozen in liquid ethane. Once frozen, the samples were transferred, stored, and imaged at cryogenic temperatures. The liposomes were attracted to the amine surface through electrostatic interactions with surface charge on the liposome.

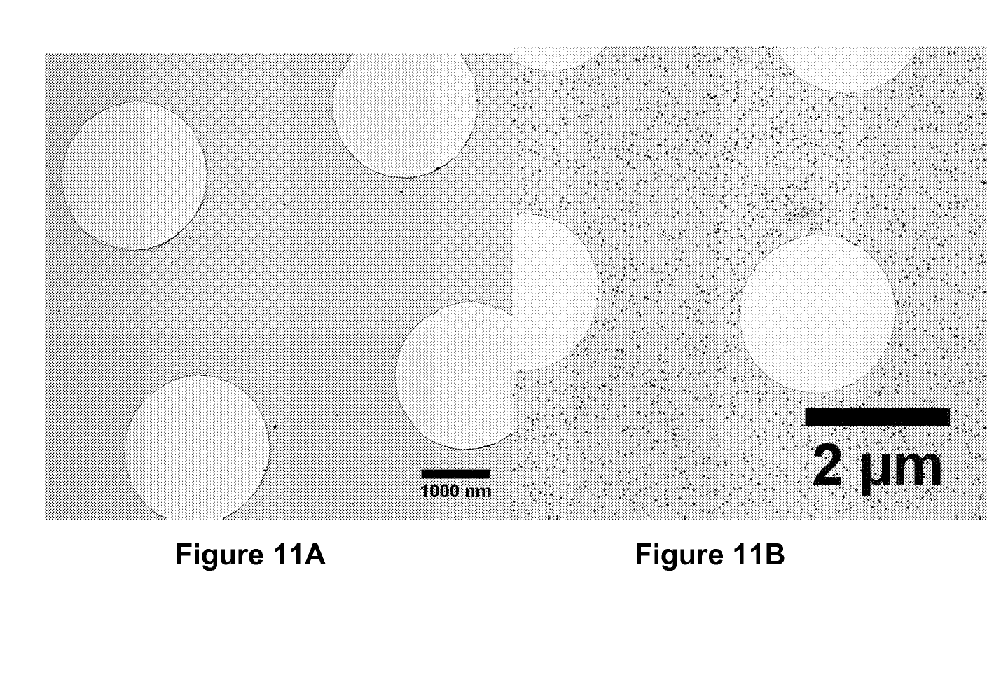

In another example of amine-functionalized perforated carbon substrates (generally used for cryo-electron microscopy), FIGS. 11A and 11B illustrate a comparison of a non-functionalized grid (FIG. 11A) with an amine-functionalized carbon substrate (FIG. 11B) for 30 nm citrate-stabilized Au nanoparticles (NIST SRM 8012), showing the dramatically improved coverage of nanoparticles, in accordance with various embodiments. A few particles stuck to the non-functionalized grid, but virtually no other particles could be found.

### Example 2

### Dicarboxylate-Functionalized Carbon Membrane

This example illustrates the efficacy of dicarboxylate-functionalized carbon substrates. Amorphous carbon films having a thickness of 3 nm were deposited on lacey carbon and copper supports, and were oxidized using UV/ozone for 5 minutes at ambient temperature and atmosphere. Subsequently, the membranes were exposed to 3-(trimethoxysilyl)propyl succinic anhydride for 18 hrs in a sealed, desiccated chamber at room temperature. The samples were then removed and rinsed in water to form a dicarboxylate on the functionalized carbon substrate surface with a net negative charge. The functionalized carbon substrates were then floated functionalized-side down on a droplet of the positively charged Au-TMAT nanoparticles for 2 minutes, followed by rinsing with deionized water.

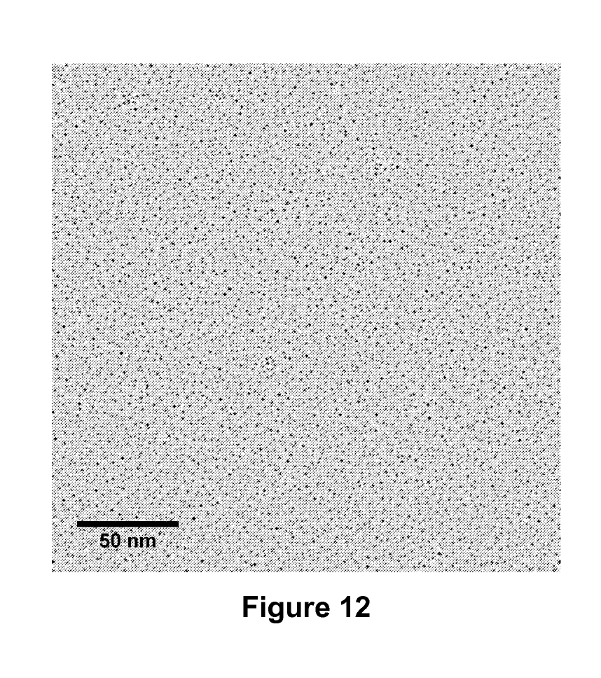

FIG. 12 is a digital image showing the coverage of 1.5 nm gold-trimethylammoniumethanethiol (TMAT)-functionalized particles deposited on the dicarboxylate-functionalized carbon membrane; in accordance with various embodiments. As illustrated, the TMAT particles are positively charged and adhere to the negatively charged dicarboxylate surface.

### Example 3

### Epoxy-Functionalized Carbon Substrates

This example illustrates the efficacy of dicarboxylate-functionalized carbon substrates. In one embodiment, epoxy-functionalized carbon substrates were produced by first surface oxidation using UV/ozone followed by immersion in a 10 mM solution 3-glycidoxypropyltrimethoxysilane in toluene for 60 minutes. Subsequently, the functionalized carbon substrate was removed and rinsed in toluene and dried in air. In various embodiments, the epoxy-functionalized carbon substrates may bind directly to primary amines, such as in lysine groups, to covalently attach biomolecules. In various embodiments, the epoxy-functionalized carbon substrates are then incubated in (e.g., floated on) a droplet of solution with the desired molecules.

In one example, an epoxy-functionalized 3 nm thick carbon on holey carbon grids were floated on a droplet of purified T3 Phage solution with a concentration of 10¹⁰ particles/ml for 20 minutes. Subsequently, the grid was removed from the droplet and then rinsed on two droplets of deionized water. Between each droplet, excess liquid was wicked away using a filter paper. Finally, the grid was floated on a solution of freshly prepared 0.5% uranyl acetate stain for 2 minutes and then removed and wicked dry.

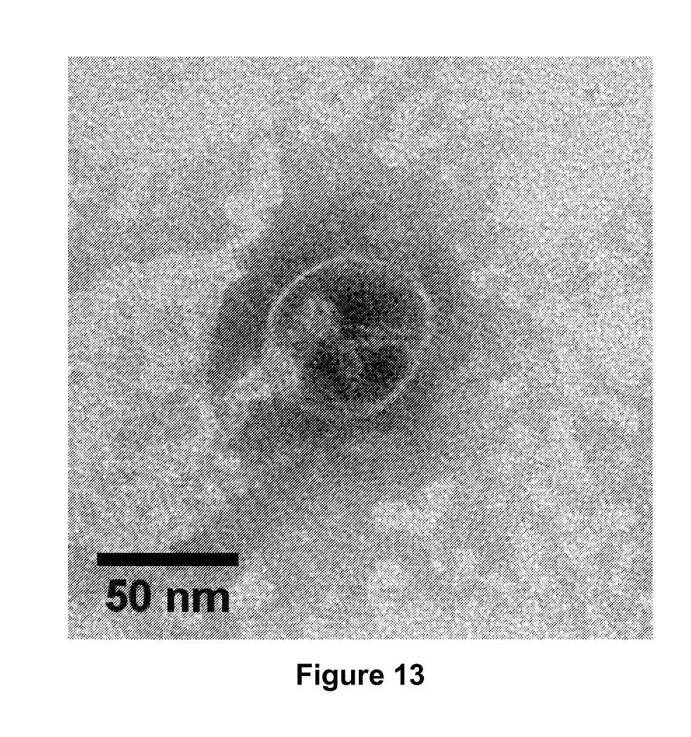

FIG. 13 illustrates a micrograph of the T3 phage on its side with an empty viral capsid and the molecular motor tail, in accordance with various embodiments. In this example, the covalent attachment of primary amines on the biomolecule to the grid improved the dispersion on the grid surface and also increased the degree of random orientation by locking the molecule in place. For single particle analysis, random orientation is difficult to achieve, particularly for anisotropic molecules due to the tendency to “lay down” on the grid surface.

### Example 4

### Protein A-Functionalized Carbon Grids

This example demonstrates the application of Protein A modified carbon film for the immunocapture and imaging of the Complex I enzyme from a mixed solution of bovine heart mitochondria (BHM), in accordance with various embodiments. To prepare these functionalized grids, Protein A was coupled to amine-functionalized carbon grids using an EDC (1-ethyl-3-[3-dimethylaminopropyl]carbodiimide hydrochloride) bifunctional linker. The grids were then rinsed and dried prior to use. In various embodiments, Protein A may be used to selectively capture the Fc region of IgG antibodies.

To prepare the Complex I samples, mitochondria proteins were extracted from homogenized rodent tissue using lauryl maltoside, which does not denature the enzymes. The extracted protein solution was then centrifuged at 16,000 rpm at 4° C. for 20 minutes. The supernatant was then removed and used for preparing the TEM sample.

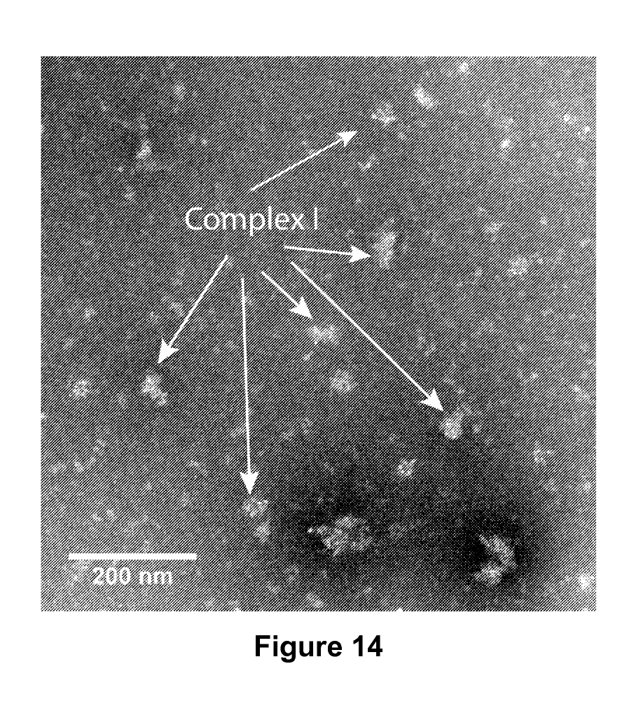

To prepare the TEM samples, Protein A grids were floated on 10 μl droplets of monoclonal antibody (mAb) for Bovine Heart Complex I at a concentration of 0.5 mg/ml for 20 minutes. Subsequently, the grids were rinsed by floating on droplets of 1× PBS pH 7.2. Between each successive step, excess liquid was wicked away using filter paper. The grids were then blocked by floating on 10 μl droplets of 1× bovine serum albumin for 20 minutes. After rinsing, the grids were then floated on 10 μl droplets of the mitochondria enzyme solution for 30 minutes to isolate the complex I enzymes. Afterwards, the grids were rinse and then stained using 1% uranyl acetate. FIG. 14 illustrates the use of Protein A modified carbon film for the immunocapture and imaging of the Complex I enzyme from a mixed solution of bovine heart mitochondria (BHM), in accordance with various embodiments.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope. Those with skill in the art will readily appreciate that embodiments may be implemented in a very wide variety of ways. This application is intended to cover any adaptations or variations of the embodiments discussed herein. Therefore, it is manifestly intended that embodiments be limited only by the claims and the equivalents thereof.

What is claimed is:

1. An electron transmissive substrate comprising a film, wherein the film comprises carbon, and wherein the film comprises at least one functionalized surface.

2. The electron transmissive substrate of claim 1, wherein the film is continuous or perforated.

3. The electron transmissive substrate of claim 2, wherein the film comprises a plurality of perforations, and wherein the perforations are patterned or random.

4. The electron transmissive substrate of claim 3, wherein the perforations have a diameter of from about 50 nm to about 5 microns.

5. The electron transmissive substrate of claim 1, wherein the film comprises amorphous carbon, a single or multi-layer graphene sheet, a holey carbon film, a reticulated carbon film, a lacey carbon film, a diamond carbon film, a carbon-filled polymer membrane, carbon black, a carbon fullerene, a carbon nanotube mat, or a combination thereof.

6. The electron transmissive substrate of claim 1, wherein the carbon film is woven or non-woven.

7. The electron transmissive substrate of claim 1, wherein the film is freestanding.

8. The electron transmissive substrate of claim 1, wherein the substrate comprises a support structure.

9. The electron transmissive substrate of claim 8, wherein the support structure comprises carbon, copper, nickel, molybdenum, beryllium, gold, silicon, GaAs, an oxide, a nitride, a polymer, or a combination thereof.

10. The electron transmissive substrate of claim 8, wherein the film spans one or more electron transmissive apertures in the support structure.

11. The electron transmissive substrate of claim 1, wherein the film is optically transmissive.

12. The electron transmissive substrate of claim 1, wherein the film has a thickness of from about 0.1 nm to about 250 nm.

13. The electron transmissive substrate of claim 1, wherein the functionalized surface comprises a compound having the formula C—R, wherein R comprises: a silane; an aryl; an alkyl; an alkenyl; an amine; a carboxyl; a carbonyl; a sulfhydryl; a phosphonate; a sulfonate; an epoxy; a chemical linker to a biomolecule, wherein the chemical linker comprises a maleimide, an NHS-ester, or a carbodiimide; or a biological molecule, wherein the biological molecule comprises a protein, an antibody, or a virus.

14. The electron transmissive substrate of claim 1, wherein the functionalized surface comprises a monolayer or a multilayer.

15. The electron transmissive substrate of claim 1, wherein the functionalized surface is hydrophilic.

16. A method of functionalizing an electron transmissive and electron conductive film, wherein the film comprises carbon, the method comprising:
surface-oxidizing at least one surface of the film, and
reacting the at least one surface of the film with one or more organosilane derivatives that form a siloxane bond with the at least one surface of the film, thereby silanizing the at least one surface of the film.

17. The method of claim 16, wherein the silanized film surface has the formula C—O—Si—R₃, C comprises the at least one surface of the film, —O—Si comprises the siloxane bond, and R comprises one or more functional groups.

18. The method of claim 16, wherein surface-oxidizing the at least one surface of the film comprises using a mild oxidant.

19. The method of claim 18, wherein the mild oxidant comprises dilute UV/ozone, ozone, H₂O₂, oxygen plasma, or an acid.

20. The method of claim 16, wherein surface-oxidizing the at least one surface of the film comprises surface-oxidizing the at least one surface to about 0.2 to about 1 —OH/nm².

21. The method of claim 16, wherein the organosilane derivative has the formula: RSiX₃, R₂SiX₂, R₃SiX, or a combination thereof, or R-silatrane (R-2,8,9-trioxa-5-aza-1-silabicyclo(3.3.3)undecane);
wherein X comprises a chloride, a bromide, an alkoxy group comprising a straight-chain or branched C1-C30 radical, a phenoxy, a benzyloxy, or a naphthoxy; and
wherein R comprises an aryl; an alkyl; an alkenyl; an amine; a carboxyl; a carbonyl; a sulfhydryl; a phosphonate; a sulfonate; an epoxy; a chemical linker to a biomolecule, wherein the chemical linker comprises a maleimide, an NHS-ester, or a carbodiimide; or a biological molecule, wherein the biological molecule comprises a protein, an antibody, or a virus.

22. The method of claim 16, wherein reacting the at least one surface of the film with one or more organosilane derivatives comprises exposing the at least one surface of the film to a vapor phase of an organosilane derivative at a temperature of from about 25° C. to about 100° C. in an ambient or inert atmosphere.

23. The method of claim 16, wherein reacting the at least one surface of the film with one or more organosilane derivatives comprises reacting the at least one surface of the film in liquid phase with the organosilane derivative dissolved or dispersed in aqueous or nonaqueous solvent.

24. The method of claim 23, wherein reacting the at least one surface of the film with one or more organosilane derivatives comprises contacting the at least one surface of the film with the liquid phase by immersion, floating, adding a droplet to the at least one surface of the film, spray coating, spin-coating, or dip-coating.

25. The method of claim 16, wherein the method further comprises heat treatment;
rinsing; reacting with a bi-functional linker, wherein the bi-functional linker comprises EDC (1-Ethyl-3-[3-dimethylaminopropyl]carbodiimide hydrochloride), SMCC (succinimidyl 4-[N-maleimidomethyl]cyclohexane-1-carboxylate), sulfo-SMCC, BS³ (Bis[sulfosuccinimidyl]suberate), sulfo-NHS, or another homobifunctional or heterobifunctional linker molecule; and conjugating a biomolecule directly to the at least one surface of the film, wherein the biomolecule comprises a nucleic acid, an antibody, a protein, a virus, an antigen, or an oligopeptide.

26. The method of claim 16, wherein the at least one surface of the film is silanized in a pattern to provide at least two regions of the at least one surface of the film with different surface chemistries.

27. The method of claim 26, wherein the pattern is a regular pattern comprising an array of functionalized regions, or an irregular pattern.

28. The method of claim 26, wherein the pattern comprises one or more areas that are not functionalized.

29. The method of claim 26, wherein the pattern comprises a microarray.
